(19) United States
(12) Patent Application Publication
(10) Pub. No.: US 2026/0190822 A1
(43) Pub. Date: Jul. 2, 2026

(54) DISPLAY PANEL AND DISPLAY APPARATUS COMPRISING THE SAME

(71) Applicant: LG Display Co., Ltd., Seoul (KR)

(72) Inventors: Suk CHOI, Paju-si (KR); Sangwook WOO, Paju-si (KR); MinHo LEE, Paju-si (KR)

(73) Assignee: LG Display Co., Ltd., Seoul (KR)

(21) Appl. No.: 19/222,489

(22) Filed: May 29, 2025

(30) Foreign Application Priority Data
Dec. 30, 2024 (KR) 10-2024-0201317

(51) Int. Cl. H10K 59/80; H10K 102/00

(52) U.S. Cl. CPC H10K 59/8792; H10K 2102/311

(57) ABSTRACT

A display panel and a display apparatus comprising the same are provided. The display panel in some examples includes a substrate and a light shielding layer on the substrate. The substrate includes a bending area, a first non-bending area, and a second non-bending area. The bending area is arranged between the first non-bending area and the second non-bending area. The light shielding layer includes a black coating layer arranged in the first non-bending area, a first black pattern layer arranged in the first non-bending area, and a second black pattern layer arranged in the second non-bending area. The first non-bending area includes a first buffer pattern, and the first buffer pattern is arranged between the black coating layer and the first black pattern layer.

### CROSS-REFERENCE TO RELATED APPLICATIONS

This application claims priority to Korean Patent Application No. 10-2024-0201317, filed in the Republic of Korea on Dec. 30, 2024, the entire disclosure of which is hereby expressly incorporated by reference for all purposes into the present application.

### BACKGROUND

### Technical Field

The present disclosure relates to a display panel and a display apparatus comprising the same, and more particularly, to a display panel in which occurrence of cracks, which can occur in and around a bending area, is suppressed or minimized, and to a display apparatus comprising the display panel.

### Description of the Related Art

Display apparatuses are mounted on electronic products or home appliances, such as televisions, monitors, laptop computers, smart phones, tablet computers, electronic pads, wearable devices, portable information devices, navigation devices, or vehicle control display devices, and are used as screens for displaying images.

Among the display apparatuses, since a liquid crystal display apparatus, a light emitting display apparatus, and an electrophoretic display apparatus can be thinned, research and development for implementing them as flexible display apparatuses are underway. The flexible display apparatus forms a display unit including a thin film transistor on a flexible substrate, and can be used in various display fields because it is possible to display an image even if it is bent like paper.

As the display apparatus becomes thinner and lighter, both a display panel and a cover window are configured in the form of a very thin film. For this reason, when an external impact is applied to the display apparatus, it is transmitted to the display panel located inside the display apparatus as it is. This eventually can cause damage to the display panel, thereby deteriorating display quality of the display panel.

Furthermore, as the display apparatus becomes thinner and lighter, heat dissipation characteristics that emit heat generated from the display panel can deteriorate. As a result, heat generated from the display panel may not be sufficiently discharged, and thus, a temperature inside the display panel can increase, whereby a problem can occur in that lifespan and efficiency of display elements provided in the display panel can be deteriorated.

Therefore, a display panel that is thin but does not cause damage to the display panel even in case of an external impact and has excellent heat dissipation performance and a display apparatus comprising the same are needed.

### SUMMARY OF THE DISCLOSURE

The present disclosure has been made in view of the above problems and it is an object of the present disclosure to provide a display panel in which bending stress which may be caused by bending of a substrate is alleviated or eliminated.

It is another object of the present disclosure is to provide a display panel in which occurrence of cracks in and around a bending area which may occur due to an external force is suppressed or minimized.

It is still another object of the present disclosure is to provide a display panel having excellent heat dissipation characteristics.

It is further still another object of the present disclosure is to provide a display apparatus comprising the above display panel.

In addition to the objects of the present disclosure as mentioned above, additional objects and features of the present disclosure will be clearly understood by those skilled in the art from the following description of the present disclosure.

In accordance with an aspect of the present disclosure, the above and other objects can be accomplished by the provision of a display panel comprising a substrate, and a light shielding layer on the substrate, wherein the substrate includes a bending area, a first non-bending area, and a second non-bending area, the bending area is arranged between the first non-bending area and the second non-bending area, the light shielding layer includes a black coating layer arranged in the first non-bending area, a first black pattern layer arranged in the first non-bending area, and a second black pattern layer arranged in the second non-bending area, the first non-bending area includes a first buffer pattern, and the first buffer pattern is arranged between the black coating layer and the first black pattern layer.

According to one embodiment of the present disclosure, the first buffer pattern can have a thickness smaller than those of the first and second non-bending areas and greater than that of the bending area.

The display panel according to one embodiment of the present disclosure can further comprise a first resin layer arranged in the first buffer pattern.

According to one embodiment of the present disclosure, the first resin layer can include a first polymer matrix, and a first thermally conductive filler dispersed in the first polymer matrix.

The display panel according to one embodiment of the present disclosure can further comprise a second resin layer arranged in an area defined by the bending area, the first non-bending area, and the second non-bending area.

According to one embodiment of the present disclosure, the second resin layer can include a second polymer matrix, and a second thermally conductive filler dispersed in the second polymer matrix.

The display panel according to one embodiment of the present disclosure can further comprise a third black pattern layer arranged between the first buffer pattern and the black coating layer.

The display panel according to one embodiment of the present disclosure can further comprise a fourth black pattern layer on the first resin layer.

According to one embodiment of the present disclosure, the fourth black pattern layer can include the same material as that of the first polymer matrix.

According to one embodiment of the present disclosure, the fourth black pattern layer can include the same material as that of the first black pattern layer.

The display panel according to one embodiment of the present disclosure can further comprise a protective layer arranged on at least one of the first black pattern layer or the second black pattern layer.

The display panel according to one embodiment of the present disclosure can further comprise an adhesive layer on the light shielding layer, a support layer on the adhesive layer, and a second buffer pattern arranged between the adhesive layer and the support layer.

According to one embodiment of the present disclosure, at least a portion of the second buffer pattern can overlap the first buffer pattern.

According to one embodiment of the present disclosure, the second buffer pattern can further comprise a third resin layer, wherein the third resin layer can include a third polymer matrix, and a third thermally conductive filler dispersed in the third polymer matrix.

The display panel according to one embodiment of the present disclosure can further comprise a hard coating layer between the adhesive layer and the support layer.

According to one embodiment of the present disclosure, the adhesive layer can include a second buffer pattern, the support layer can include a third buffer pattern, and the second buffer pattern and the third buffer pattern can face each other.

The display panel according to one embodiment of the present disclosure can further comprise a third resin layer arranged in the second buffer pattern and the third buffer pattern, wherein the third resin layer can include a third polymer matrix, and a third thermally conductive filler dispersed in the third polymer matrix.

According to another embodiment of the present disclosure, a display device comprising the above display panel is provided.

### BRIEF DESCRIPTION OF THE DRAWINGS

The above and other objects, features and other advantages of the present disclosure will be more clearly understood from the following detailed description taken in conjunction with the accompanying drawings, in which:

FIG. 1 is a schematic plan view illustrating a display panel according to one or more embodiments of the present disclosure;

FIG. 2 is a schematic cross-sectional view taken along line I-I′ shown in FIG. 1;

FIG. 3 is a schematic cross-sectional view illustrating a state after bending of a display panel according to an embodiment of the present disclosure, which is shown in FIG. 2;

FIG. 4 is a schematic cross-sectional view illustrating a display panel according to embodiments of the present disclosure;

FIG. 5 is a schematic cross-sectional view illustrating a display panel according to embodiments of the present disclosure;

FIG. 6 is a schematic cross-sectional view illustrating a display panel according to embodiments of the present disclosure;

FIG. 7 is a schematic cross-sectional view illustrating a display panel according to embodiments of the present disclosure;

FIG. 8 is a schematic cross-sectional view illustrating a display panel according to embodiments of the present disclosure;

FIG. 9 is a schematic cross-sectional view illustrating a display panel according to embodiments of the present disclosure;

FIG. 10 is a schematic cross-sectional view illustrating a display panel according to embodiments of the present disclosure;

FIG. 11 is a schematic cross-sectional view illustrating a display panel according to embodiments of the present disclosure;

FIG. 12 is a schematic cross-sectional view illustrating a display panel according to embodiments of the present disclosure;

FIG. 13 is a schematic cross-sectional view illustrating a display panel according to embodiments of the present disclosure;

FIG. 14 is a schematic cross-sectional view illustrating a display panel according to embodiments of the present disclosure;

FIGS. 15A, 15B and 15C are schematic cross-sectional views illustrating various shapes of a protective layer according to embodiments of the present disclosure; and

FIGS. 16A, 16B and 16C are schematic cross-sectional views illustrating various shapes of a first buffer pattern according to embodiments of the present disclosure.

### DETAILED DESCRIPTION OF THE DISCLOSURE

Advantages and features of the present disclosure and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete and will fully convey the scope of the present disclosure to those skilled in the art. Further, the present disclosure is only defined by scopes of claims.

A shape, a size, a ratio, an angle and a number disclosed in the drawings for describing embodiments of the present disclosure are merely an example and thus, the present disclosure is not limited to the illustrated details. Like reference numerals refer to like elements throughout the disclosure. In the following description, when the detailed description of the relevant known function or configuration is determined to unnecessarily obscure the important point of the present disclosure, the detailed description will be omitted.

In a case where ‘comprise’, ‘have’ and ‘include’ described in the present disclosure are used, another portion can be added unless ‘only’ is used. The terms of a singular form can include plural forms unless referred to the contrary.

In construing an element, the element is construed as including an error band although there is no explicit description.

In describing a position relationship, for example, when the position relationship is described as ‘upon’, ‘above’, ‘below’ and ‘next to’, one or more portions can be arranged between two other portions unless ‘just’ or ‘direct’ is used.

In describing a position relationship, for example, when the position relationship is described as ‘upon’, ‘above’, ‘below’, and ‘next to’, one or more portions can be arranged between two other portions unless ‘just’ or ‘direct’ is used. Spatially relative terms such as “below”, “beneath”, “lower”, “above”, and “upper” can be used herein to easily describe a relationship of one element or elements to another element or elements as illustrated in the figures. It will be understood that these terms are intended to encompass different orientations of the device in addition to the orientation depicted in the figures. For example, if the device illustrated in the figure is reversed, the device described to be arranged “below”, or “beneath” another device can be arranged “above” another device. Therefore, an example term “below or beneath” can include “below or beneath” and “above” orientations. Likewise, an example term “above” or “on” can include “above” and “below or beneath” orientations.

In describing a temporal relationship, for example, when the temporal order is described as “after,” “subsequent,” “next,” and “before,” a case which is not continuous can be included, unless “just” or “direct” is used.

It will be understood that, although the terms “first,” “second,” etc. can be used herein to describe various elements, these elements should not be limited by these terms. These terms are only used to distinguish one element from another and may not define order or sequence. For example, a first element could be termed a second element, and, similarly, a second element could be termed a first element, without departing from the scope of the present disclosure.

It should be understood that the term “at least one” includes all combinations related with any one item. For example, “at least one among a first element, a second element and a third element” can include all combinations of two or more elements selected from the first, second and third elements as well as each element of the first, second and third elements. Further, the term “can” fully encompasses all the meanings and coverages of the term “may” and vice versa.

Features of various embodiments of the present disclosure can be partially or overall coupled to or combined with each other, and can be variously inter-operated with each other and driven technically as those skilled in the art can sufficiently understand. The embodiments of the present disclosure can be carried out independently from each other, or can be carried out together in a co-dependent relationship.

In adding reference numerals to elements of each drawing describing embodiments of the present disclosure, the same elements can have the same reference numerals as possible even though they are shown on different drawings.

In the embodiments of the present disclosure, a source electrode and a drain electrode are distinguished for convenience of description, and the source electrode and the drain electrode can be interchanged. In addition, the source electrode of one embodiment can be a drain electrode in another embodiment, and the drain electrode of one embodiment can be a source electrode in another embodiment.

In some embodiments of the present disclosure, although a source connection portion and a source electrode are distinguished and a drain connection portion and a drain electrode are distinguished for convenience of description, the embodiments of the present disclosure are not limited thereto. The source connection portion can be a source electrode, and the drain connection portion can be a drain electrode. In addition, the source connection portion can be a drain electrode, and the drain connection portion can be a source electrode.

Now referring to the drawings, various embodiments of the present disclosure will be discussed. All the components of each display panel and each display apparatus according to all embodiments of the present disclosure are operatively coupled and configured.

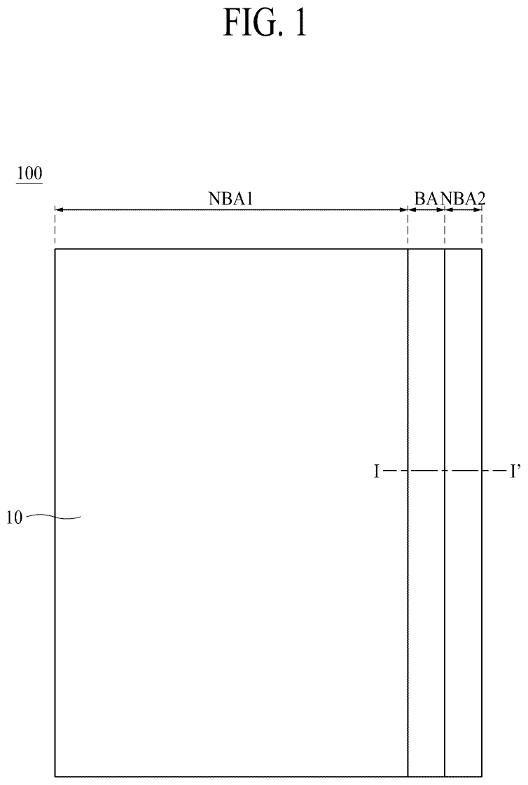

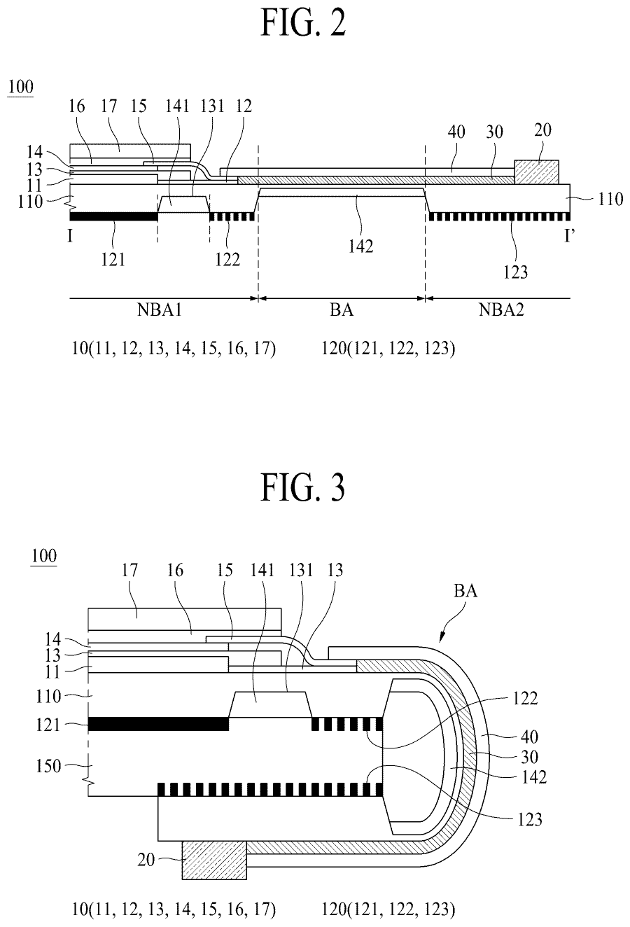

FIG. 1 is a schematic plan view illustrating a display panel according to one or more embodiments of the present disclosure, and FIG. 2 is a schematic cross-sectional view taken along line I-I′ shown in FIG. 1. Hereinafter, each portion constituting the display panel 100 is shown on a scale different from an actual scale for convenience of description, and thus is not limited to a scale shown in the drawings.

Referring to FIGS. 1 and 2, according to embodiments of the present disclosure, the display panel 100 can include a substrate 110, a display unit 10 arranged on a first non-bending area NBA1 of the substrate 110, a driving integrated circuit 20 arranged on a second non-bending area NBA2 of the substrate 110, a line 30 arranged on at least a portion of the first non-bending area NBA1 of the substrate 110 and at least a portion of the bending area BA and the second non-bending area NBA2, a coating layer 40 on the line 30, and a light shielding layer 120 arranged on another surface of the substrate 110.

According to an embodiment of the present disclosure, the display panel 100 can be coupled to a cover window to display an image or sense a user's touch.

The display unit 10 can include a pixel array 11, a display pad 12, an encapsulation layer 13, a touch electrode 14, a touch pad 15, a film adhesive member 16, and a functional film 17.

The pixel array 11 can be formed on the first non-bending area NBA1 of the substrate 110, and can display an image.

The pixel array 11 can be arranged in a pixel area defined by signal lines provided on the substrate 110. The pixel array 11 can include a plurality of pixels that display an image in accordance with a signal supplied to the signal lines.

At this time, each of the plurality of pixels can include a circuit layer including a driving thin film transistor provided in the pixel area, an anode electrode electrically connected to the driving thin film transistor, a light emitting element layer formed on the anode electrode, and a cathode electrode electrically connected to the light emitting element layer.

The driving thin film transistor is provided in a transistor area of each pixel area defined on the substrate 110, and can include a gate electrode, a gate insulating layer, a semiconductor layer, a source electrode and a drain electrode. The semiconductor layer of the thin film transistor can include silicon such as amorphous silicon (a-Si), polysilicon (poly-Si), or low-temperature polysilicon (LTPS), or an oxide such as indium-gallium-zinc-oxide (IGZO).

The anode electrode is provided in the form of a pattern in an opening area defined in each pixel area and electrically connected to the driving thin film transistor.

The light emitting element layer can include an organic light emitting element. The organic light emitting element can be formed in a structure in which a hole injection layer, a hole transport layer, an organic light emitting layer, an electron transport layer, and an electron injection layer are stacked. In this case, one or more of the hole injection layer, the hole transport layer, the electron transport layer, and the electron injection layer can be omitted.

The cathode electrode can be formed on the light emitting element layer provided in each pixel area and thus electrically connected to the light emitting element layer.

The display pad 12 can be arranged on one side of the pixel array 11. The display pad 12 can be electrically connected to the driving integrated circuit 20 through the line 30.

The encapsulation layer 13 can be formed on the pixel array 11 to prevent oxygen or moisture from being permeated into the light emitting element layer of the pixel array 11. The encapsulation layer 13 can be formed in a multi-layered structure in which an organic material layer and an inorganic material layer are alternately stacked. The inorganic material layer can serve to prevent oxygen or moisture from being permeated into the light emitting element layer of the pixel array 11. The organic material layer can be formed to be relatively thicker than the inorganic material layer to cover particles that can occur during a manufacturing process. For example, the encapsulation layer can include a first inorganic layer, an organic layer on the first inorganic layer, and a second inorganic layer on the organic layer. In this case, the organic layer can be defined as a particle cover layer.

The touch electrode 14 is arranged on the encapsulation layer 13 and serves as a touch sensor for sensing a user's touch. The touch electrode 14 can include a touch electrode layer arranged on the encapsulation layer 13 that overlaps the pixel array 11, and a dielectric layer covering the touch electrode layer.

The touch pad 15 can be arranged on one edge portion of the touch electrode 14 corresponding to one edge of the substrate 110. The touch pad 15 can be in contact with the line 30 arranged on the substrate 110. The touch pad 15 can be electrically connected to the driving integrated circuit 20 through the line 30.

The functional film 17 is attached onto the touch electrode 14 via the film adhesive member 16. The film adhesive member 16 can include one of, for example, a pressure sensitive adhesive (PSA), an optical clear adhesive (OCA), and an optical clear resin (OCR).

The functional film 17 can include an anti-reflective layer (or an anti-reflective film) for improving outdoor visibility and a contrast ratio of an image displayed on the display unit 10 of the electronic device by preventing reflection of external light. The anti-reflective layer can include a circularly polarized layer (or a circularly polarized film) that blocks reflective light that is incident through the cover window and then reflected by a thin film transistor and/or lines arranged in the pixel array to proceed to the cover window again.

The functional film 17 can further include a barrier layer (or barrier film) for primarily preventing permeation of moisture or oxygen, and the barrier layer can be made of a material having low moisture permeability, for example, a polymer material.

The driving integrated circuit 20 is arranged in the second non-bending area NBA2 defined in the substrate 110 by a chip bonding process or a surface packaging process. The driving integrated circuit 20 is electrically connected to the line 30 and is electrically connected to the pixel array 11 through the display pad 12. The driving integrated circuit 20 displays an image on each pixel arranged in the pixel array 11 through the line 30.

The display panel 100 according to an embodiment of the present disclosure can include a coating layer 40 covering the bending area BA of the substrate 110. The coating layer 40 can be referred to as a line protection layer, a micro-coating layer, or a micro-cover layer.

The coating layer 40 can be formed on the substrate 110. In more detail, the coating layer 40 can be arranged on the bending area BA of the substrate 110 and on portions of the first and second non-bending areas NBA1 and NBA2 adjacent to the bending area BA. In this case, the coating layer 40 can cover the line 30 arranged on the substrate 110. Accordingly, the coating layer 40 can protect the line 30 from external impact and prevent moisture permeation to the line 30.

The substrate 110 can be a base member or a base substrate for supporting or forming various components of the display apparatus. The substrate 110 can be made of a material having flexibility. The substrate 110 according to an embodiment of the present disclosure can be made of a thin glass material having flexibility, but the embodiments of the present disclosure are not limited thereto. For example, the substrate 110 according to another embodiment of the present disclosure can be made of a plastic material such as polyimide.

The substrate 110 can include a bending area BA, a first non-bending area NBA1, and a second non-bending area NBA2.

The bending area BA of the substrate 110 means, for example, an area that can be freely bent to have a predetermined radius of curvature. Accordingly, the display panel 100 can have a thin bezel width by bending the bending area BA of the substrate 110 to have a predetermined radius of curvature. The bending area BA of the substrate 110 can be formed by adjusting a predetermined area of the substrate 110 to have a predetermined thickness through etching.

The light shielding layer 120 can include a black coating layer 121 arranged in the first non-bending area NBA1, a first black pattern layer 122 arranged in the first non-bending area NBA1, and a second black pattern layer 123 arranged in the second non-bending area NBA2.

The light shielding layer 120 can be made of, for example, a black matrix formed by a thermosetting method after dispersing carbon black in a polymer resin. The light shielding layer 120 can be formed by a method of printing black ink, but an embodiment of the present disclosure is not limited thereto, and other known materials that can be used as the light shielding layer 120 can be used to form the light shielding layer 120.

Referring to FIG. 2, the black coating layer 121 can be arranged in a portion of the first non-bending area NBA1. The black coating layer 121 can overlap the display unit 10. In more detail, the black coating layer 121 can overlap the pixel array 11.

The first black pattern layer 122 can be arranged in an area of the first non-bending area NAB1, in which the black coating layer 121 is not arranged. In more detail, the first black pattern layer 122 can be arranged in an area of the first non-bending area NBA1 of the substrate 110, in which the black coating layer 121 is not arranged and with which the bending area is in contact. At least a portion of the first black pattern layer 122 can overlap the display unit 10, and another portion thereof may not overlap the display unit 10. The first black pattern layer 122 can overlap at least a portion of the second black pattern layer 123 after bending.

The first black pattern layer 122 can relieve bending stress caused by bending of the substrate 110, and can suppress or minimize occurrence of cracks in or around one side (an area where the first non-bending area NBA1 is in contact with the bending area BA) of the bending area BA having a relatively thin thickness in the first non-bending areas NBA1.

Further, as the first black pattern layer 122 is formed to include a certain pattern, a heat path can be formed between the formed patterns. Therefore, the first black pattern layer 122 can discharge heat, which is discharged from the display unit 10 and the line 30 and is moored in the display panel 100, to the outside of the display panel 100 by heat conduction, convection, or radiation through a heat path. Therefore, the display panel 100 according to an embodiment of the present disclosure can have excellent heat dissipation characteristics.

The second black pattern layer 123 can be arranged in the second non-bending area NBA2.

The second black pattern layer 123 can relieve bending stress caused by bending of the substrate 110. The second black pattern layer 123 can suppress or minimize occurrence of cracks in or around the other side (an area where the second non-bending area NBA2 is in contact with the bending area BA) of the bending area BA having a relatively thin thickness in the second non-bending areas NBA2.

Further, as the second black pattern layer 123 is formed to include a certain pattern, a heat path can be formed between the formed patterns. Therefore, the second black pattern layer 123 can discharge heat, which is discharged from the driving integrated circuit 20 and the line 30 and is moored in the display panel 100, to the outside of the display panel 100 by heat conduction, convection, or radiation through a heat path. Therefore, the display panel 100 according to an embodiment of the present disclosure can have excellent heat dissipation characteristics.

According to an embodiment of the present disclosure, the first non-bending area NBA1 can include a first buffer pattern 131. In more detail, the first non-bending area NBA1 can include a first buffer pattern 131 arranged between the black coating layer 121 and the first black pattern layer 122.

When the bending area BA of the substrate 110 is bent at a predetermined radius of curvature, the first buffer pattern 131 disperses bending stress caused by bending of the substrate 110 and provides flexibility to the substrate 110 to suppress or minimize cracks that can occur in and around the bending area BA due to an external force.

According to an embodiment of the present disclosure, the bending area BA can have a thickness smaller than those of the first non-bending area NBA1 and the second non-bending area NBA2.

The bending area BA is designed to have a thickness smaller than those of the first non-bending area NBA1 and the second non-bending area NBA2, so that the substrate 110 can be bent with a predetermined radius of curvature, and cracks may not occur in and around the bending area BA.

The first buffer pattern 131 has a bottom surface and a sidewall. A thickness of the first buffer pattern 131 refers to a distance between the bottom surface of the first buffer pattern 131 and an upper surface of the substrate 110. The upper surface of the substrate 110 refers to the surface on which the pixel array 11 is arranged, and a lower surface of the substrate 110 refers to the surface on which the light shielding layer 120 is arranged.

The first buffer pattern 131 can have a thickness less than those of the first and second non-bending areas NBA1 and NBA2 of the substrate 110. Further, the first buffer pattern 131 can have a thickness greater than that of the bending area BA of the substrate 110.

When the first buffer pattern 131 has the same thickness as that of the bending area BA, the first buffer pattern 131 may not sufficiently withstand the bending stress caused by bending of the substrate 110, whereby cracks can occur in the first buffer pattern 131. Therefore, the first buffer pattern 131 can be designed to have a thickness greater than that of the bending area BA.

Therefore, as described above, the first buffer pattern 131 can be designed to have a thickness smaller than those of the first non-bending area NBA1 and the second non-bending area NBA2 in order to disperse bending stress caused by bending of the substrate 110 and give flexibility to the substrate 110.

The first buffer pattern 131 is shown to have a trapezoidal shape, but an embodiment of the present disclosure is not limited thereto. The first buffer pattern 131 can be designed to have various shapes, as necessary, such as a semicircular shape, a stepwise shape, a square shape, and a pentagonal shape, in addition to the trapezoidal shape.

The display panel 100 according to an embodiment of the present disclosure can further include a first resin layer 141 arranged in the first buffer pattern 131.

The first resin layer 141 can be arranged to fill an area defined by the first buffer pattern 131. The first resin layer 141 can be referred to as being arranged inside the first buffer pattern 131. A space defined by the bottom surface and the sidewall of the first buffer pattern 131 can be referred to as the inside of the first buffer pattern 131.

The first resin layer 141 can include a polymer resin having a higher elastic modulus than the substrate 110. Accordingly, the first buffer pattern 131 and the first resin layer 141 arranged in the first buffer pattern 131 can relieve bending stress caused by bending of the substrate 110, and can suppress or minimize occurrence of cracks in and around the bending area BA due to an external force.

According to an embodiment of the present disclosure, the first resin layer 141 can include a first polymer matrix.

The first polymer matrix is a material formed from a binder compound, and is a base material constituting the first resin layer 141. The first polymer matrix can be a polymer resin having heat resistance and a higher elastic modulus than the substrate 110.

The first polymer matrix can be formed by polymerization of a binder compound. The binder compound forming the first polymer matrix can be a thermosetting or thermoplastic polymer resin. For example, the thermosetting polymer resin can be one type of compound selected from a group consisting of epoxy-based, urethane-based, ester-based, and polyimide-based resins, or a mixture or copolymer of two or more types selected from the group. Further, the thermoplastic polymer resin can be one type of compound or a mixture or copolymer of two or more types selected from polyamide (PA), polyester, polyketone, polyolefin, polyphenylene sulfide (PPS), polyether ether ketone (PEEK), polyphenylene oxide (PPO), polyethersulfone (PES), and polyetherimide (PEI), but is not limited thereto.

The display panel 100 according to an embodiment of the present disclosure can further include a second resin layer 142 arranged in an area defined by the bending area BA, the first non-bending area NBA1, and the second non-bending area NBA2.

The second resin layer 142 can be arranged on a lower end of the bending area BA. In more detail, the second resin layer 142 can be arranged on the lower end of the bending area BA and in the area defined by the first non-bending area NBA1 and the second non-bending area NBA2.

When the second resin layer 142 is arranged on the lower end of the bending area BA and in an area defined by the first non-bending area NBA1 and the second non-bending area NBA2, bending stress caused by bending of the bending area BA at a predetermined radius of curvature can be alleviated, and occurrence of cracks in and around the bending area BA can be suppressed or minimized.

According to an embodiment of the present disclosure, the second resin layer 142 can include a second polymer matrix.

The second polymer matrix is a material formed from a binder compound, and is a base material constituting the second resin layer 142. The second polymer matrix can be a polymer resin having heat resistance and a higher elastic modulus than the substrate 110.

The second polymer matrix can be formed by polymerization of the binder compound. The binder compound forming the second polymer matrix can be a thermosetting or thermoplastic polymer resin.

The second polymer matrix can be formed by polymerization of the same binder compound as that of the first polymer matrix. A detailed type of the binder compound is the same as that described above in the first polymer matrix, and thus will be omitted.

FIG. 3 is a schematic cross-sectional view illustrating a state after bending of a display panel 100 according to an embodiment of the present disclosure, which is shown in FIG. 2.

Hereinafter, portions already described will be omitted to avoid redundancy.

Referring to FIG. 3, the substrate 110 can be bent such that the bending area BA has a predetermined radius of curvature.

The first non-bending area NBA1 of the substrate 110 is an area in which the display unit 10 is arranged on the substrate 110, and can overlap the second non-bending area NBA2 after bending.

The driving integrated circuit 20 can be arranged in the second non-bending area NBA2 defined in the substrate 110. The driving integrated circuit 20 can overlap the display unit 10 after bending.

The coating layer 40 can allow the line 30 to be positioned on a neutral plane of the bending area BA when the bending area BA of the substrate 110 is bent in a curved shape. For example, when the bending area BA of the substrate 110 is bent in a curved shape, a neutral surface having a tensile force and a compressive force of 0 exists between the substrate 110 and the coating layer 40. Accordingly, the coating layer 40 can include a material having a higher elastic modulus (or Young's modulus) than the substrate 110 so that the line 30 can be positioned on the neutral surface of the bending area BA. Accordingly, since the line 30 in the bending area BA is positioned on the neutral surface between the coating layer 40 and the substrate 110, when the bending area BA of the substrate 110 is bent in a curved shape, the line 30 is subjected to bending stress of 0, whereby the line 30 can be bent without being damaged by bending stress.

In addition, when the second resin layer 142 is arranged on the lower end of the bending area BA and in the area defined by the first non-bending area NBA1 and the second non-bending area NBA2, the thickness of the coating layer 40 formed on the upper end of the bending area BA and the thickness of the second resin layer 142 formed on the lower end of the bending area BA can be appropriately adjusted so that the line 30 arranged on the bending area BA is positioned on the neutral surface of the bending area BA.

The black coating layer 121 can overlap at least a portion of the second black pattern layer 123 after bending.

The first buffer pattern 131 can overlap at least a portion of the second black pattern layer 123 after bending.

According to an embodiment of the present disclosure, the substrate 110 can be fixed in a bent state by a fixed layer 150 after bending. The fixed layer 150 can include an adhesive layer 151 and a support layer 152, and can further include a hard coating layer 153, a back plate member, a back plate bonding member, and the like, if necessary. Details will be described later.

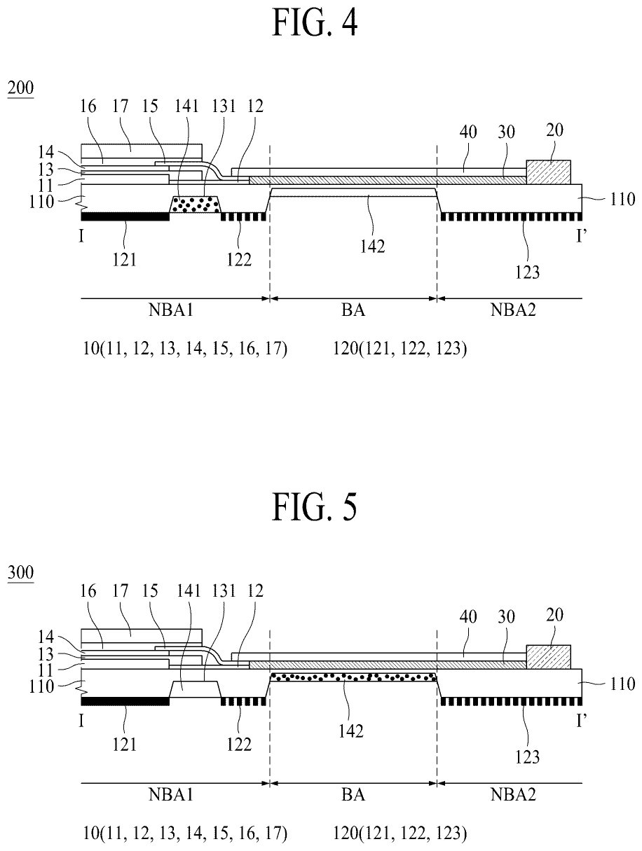

FIG. 4 is a schematic cross-sectional view illustrating a display panel 200 according to another embodiment of the present disclosure.

Referring to FIG. 4, the display panel 200 according to another embodiment of the present disclosure has the same structure as that of the display panel 100 according to an embodiment of the present disclosure, but is different in that the first resin layer 141 further includes a first thermally conductive filler dispersed in the first polymer matrix. Hereinafter, only portions different from the display panel 100 according to an embodiment of the present disclosure will be described.

According to another embodiment of the present disclosure, the first resin layer 141 can include a first polymer matrix and a first thermally conductive filler dispersed in the first polymer matrix.

The first thermally conductive filler gives insulation to the first resin layer 141 and simultaneously improves heat dissipation performance. The first thermally conductive filler is dispersed in the first polymer matrix. The first thermally conductive filler can have a particle shape or a fiber shape. When the first thermally conductive filler has a particle shape, dispersibility can be improved through surface treatment, coupling agent, or the like of the filler. When the first thermally conductive filler has a fiber shape, its orientation can be controlled so that the filler can have anisotropy in the first polymer matrix through a solvent, a surface treatment agent, or the like. When at least one of a particle shaped filler with improved dispersibility or a fiber shaped filler with controlled orientation is used as the first thermally conductive filler, the first resin layer 141 can have excellent insulation and thermal conductivity.

The first thermally conductive filler can be metal, an inorganic material, an organic material, or their mixture. For example, the first thermally conductive filler can include one or more selected from a metal powder such as aluminum (Al), nickel (Ni), copper (Cu), tin (Sn), zinc (Zn), tungsten (W), iron (Fe), silver (Ag) and gold (Au), an inorganic material such as calcium carbonate (CaCO₃), aluminum oxide (Al₂O₃), aluminum hydroxide (Al(OH)₃), silicon carbide (SiC), boron nitride (BN) and aluminum nitride (AlN), and an organic material such as graphite, graphene, carbon nanotube (CNT) and carbon nanofibers (CNF). Particularly, it is appropriate that the first thermally conductive filler includes an organic material such as graphite, graphene, carbon nanotube (CNT), and carbon nanofiber (CNF) in consideration of dispersibility, particle size, and thermal conductivity in the first polymer matrix. Further, it is more appropriate in terms of thermal conductivity that the first thermally conductive filler includes both a particle shaped filler and a fibrous filler.

The display panel 200 according to another embodiment of the present disclosure can effectively reduce heat generated from the display unit 10 as the first resin layer 141 includes the first thermally conductive filler.

FIG. 5 is a schematic cross-sectional view illustrating a display panel 300 according to another embodiment of the present disclosure.

Referring to FIG. 5, the display panel 300 according to another embodiment of the present disclosure has the same structure as that of the display panel 100 according to an embodiment of the present disclosure, but is different in that the second resin layer 142 further includes a second thermally conductive filler dispersed in the second polymer matrix. Hereinafter, only portions different from the display panel 100 according to an embodiment of the present disclosure will be described.

According to another embodiment of the present disclosure, the second resin layer 142 can include a second polymer matrix and a second thermally conductive filler dispersed in the second polymer matrix.

The second thermally conductive filler gives insulation to the second resin layer 142 and simultaneously improves heat dissipation performance. The second thermally conductive filler is dispersed in the second polymer matrix. The second thermally conductive filler can have a particle shape or a fiber shape. When the second thermally conductive filler has a particle shape, dispersibility can be improved through surface treatment, coupling agent, or the like of the filler. When the second thermally conductive filler has a fiber shape, its orientation can be controlled so that the filler can have anisotropy in the second polymer matrix through a solvent, a surface treatment agent, or the like. When at least one of a particle shaped filler with improved dispersibility or a fiber shaped filler with controlled orientation is used as the second thermally conductive filler, the second resin layer 142 can have excellent thermal conductivity.

The second thermally conductive filler can be the same as the first thermally conductive filler. A detailed type of the second thermally conductive filler is the same as that described above in the first thermally conductive filler, and thus will be omitted.

The display panel 300 according to another embodiment of the present disclosure can have excellent heat dissipation characteristics by effectively reducing heat generated from the line 30 as the second resin layer 142 includes the second thermally conductive filler.

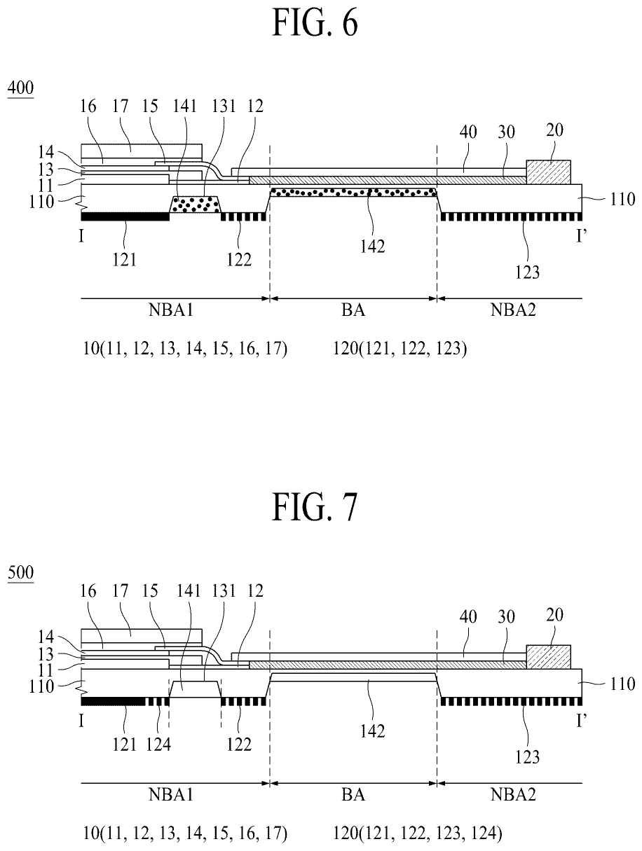

FIG. 6 is a schematic cross-sectional view illustrating a display panel 400 according to another embodiment of the present disclosure.

Referring to FIG. 6, the display panel 400 according to another embodiment of the present disclosure has the same structure as that of the display panel 100 according to an embodiment of the present disclosure, but is different in that the first resin layer 141 further includes a first thermally conductive filler dispersed in the first polymer matrix, and the second resin layer 142 further includes a second thermally conductive filler dispersed in the second polymer matrix. Hereinafter, only portions different from the display panel 100 according to an embodiment of the present disclosure will be described.

The display panel 400 according to another embodiment of the present disclosure can have excellent heat dissipation characteristics by effectively reducing heat generated from the display unit 10 and the line 30 as the first resin layer 141 includes the first thermally conductive filler and the second resin layer 142 includes the second thermally conductive filler.

FIG. 7 is a schematic cross-sectional view illustrating a display panel 500 according to another embodiment of the present disclosure.

Referring to FIG. 7, the display panel 500 according to another embodiment of the present disclosure has the same structure as that of the display panel 100 according to an embodiment of the present disclosure, but is different in that the display panel 500 further includes a third black pattern layer 124. Hereinafter, only portions different from the display panel 100 according to an embodiment of the present disclosure will be described.

The display panel 500 according to another embodiment of the present disclosure can further include a third black pattern layer 124 arranged between the first buffer pattern 131 and the black coating layer 121.

The third black pattern layer 124 can relieve bending stress caused by bending of the substrate 110, and can suppress or minimize occurrence of cracks in or around one side (an area where the first non-bending area NBA1 is in contact with the bending area BA) of the bending area BA having a relatively thin thickness in the first non-bending area NBA1.

In addition, the third black pattern layer 124 and the first black pattern layer 122 can discharge heat emitted from the display unit 10 and the line 30 and moored in the display panel 100 to the outside of the display panel 500 by heat conduction, convection, or radiation through a heat path. Accordingly, the display panel 500 according to another embodiment of the present disclosure can have excellent heat dissipation characteristics.

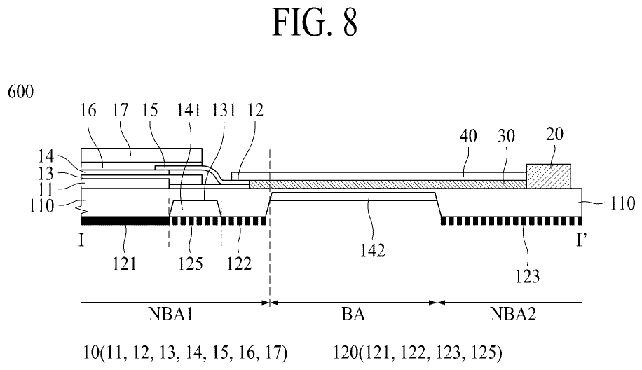

FIG. 8 is a schematic cross-sectional view illustrating a display panel 600 according to another embodiment of the present disclosure.

Referring to FIG. 8, the display panel 600 according to another embodiment of the present disclosure has the same structure as that of the display panel 100 according to an embodiment of the present disclosure, but is different in that the display panel 600 further includes a third black pattern layer 124. Hereinafter, only portions different from the display panel 100 according to an embodiment of the present disclosure will be described.

The display panel 600 according to another embodiment of the present disclosure can further include a fourth black pattern layer 125 on the first resin layer 141.

The fourth black pattern layer 125 can be formed on the first resin layer 141. The fourth black pattern layer 125 can relieve bending stress caused by bending of the substrate 110 together with the first black pattern layer 122, and can suppress or minimize occurrence of cracks in and around one side (an area where the first non-bending area NBA1 is in contact with the bending area BA) of the bending area BA having a relatively thin thickness in the first non-bending area NBA1.

Further, as the fourth black pattern layer 125 is formed to include a certain pattern, a heat path can be formed between the formed patterns. Therefore, the fourth black pattern layer 125 can discharge heat, which is discharged from the display unit 10 and the line 30 together with the first black pattern layer 122 and is moored in the display panel 100, to the outside of the display panel 100 through a heat path by heat conduction, convection, or radiation. Therefore, the display panel 600 according to another embodiment of the present disclosure can have excellent heat dissipation characteristics.

According to another embodiment of the present disclosure, the fourth black pattern layer 125 can include the same material as that of the first black pattern layer 122.

When the fourth black pattern layer 125 includes the same material as that of the first black pattern layer 122, the fourth black pattern layer 125 can be formed simultaneously with the first black pattern layer 122. Therefore, without adding the step of forming the fourth black pattern layer during a manufacturing process of the display panel, the first black pattern layer 122 and the fourth black pattern layer 125 can be formed simultaneously on the substrate 110 in the step of forming the first black pattern layer 122.

The fourth black pattern layer 125 can include the same material as that of the first polymer matrix.

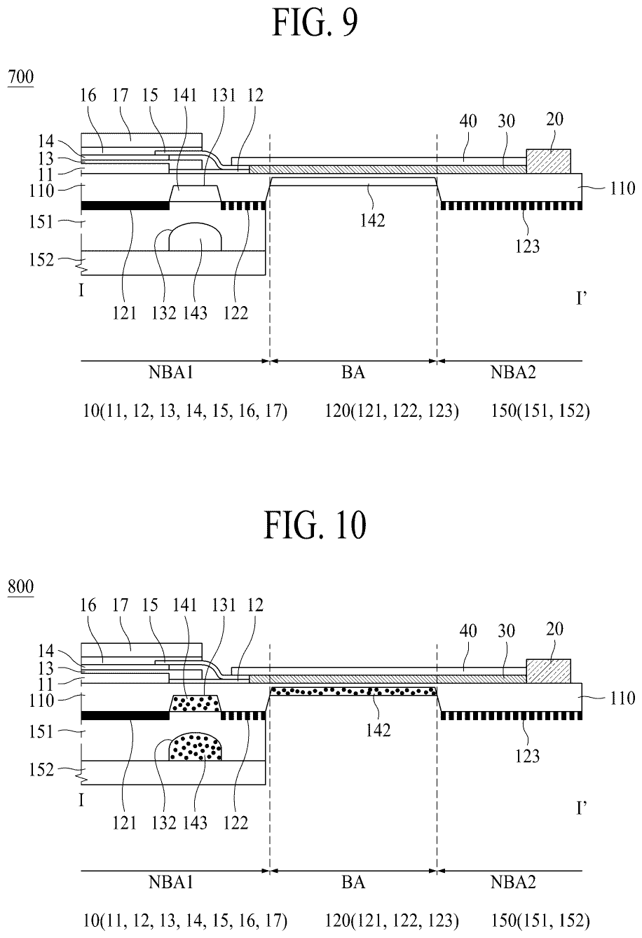

FIG. 9 is a schematic cross-sectional view illustrating a display panel 700 according to another embodiment of the present disclosure.

Referring to FIG. 9, the display panel 700 according to another embodiment of the present disclosure has the same structure as that of the display panel 100 according to an embodiment of the present disclosure, but is different in that the display panel 700 further includes an adhesive layer 151, a support layer 152 on the adhesive layer 151, and a second buffer pattern 132 arranged between the adhesive layer 151 and the support layer 152. Hereinafter, only portions different from the display panel 100 according to an embodiment of the present disclosure will be described.

The display panel 700 according to another embodiment of the present disclosure can further include an adhesive layer 151 on the light shielding layer 120, a support layer 152 on the adhesive layer 151, and a second buffer pattern 132 arranged between the adhesive layer 151 and the support layer 152.

The adhesive layer 151 can be formed on the substrate 110 to adhere the first non-bending area NBA1 of the substrate 110 to the support layer 152. In more detail, the adhesive layer 151 can be formed on the substrate 110, the black coating layer 121, the first buffer pattern 132, and the first black pattern layer 122 to adhere the first non-bending area NBA1 of the substrate 110 to the support layer 152.

The adhesive layer 151 can include, for example, any one of a Pressure Sensitive Adhesive (PSA), an Optical Clear Adhesive (OCA), or an Optical Clear Resin (OCR).

The support layer 152 can be bonded or attached onto the substrate 110. For example, the support layer 152 can be bonded or attached onto the substrate 110 by the adhesive layer 151. In more detail, the support layer 152 can be arranged on the adhesive layer 151. The support layer 152 can also be arranged on the second buffer pattern 132.

The support layer 152 can be formed of a polymer material such as a polymer resin such as polycarbonate (PC), polyimide (PI), polyethylene naphthalate (PEN), polyethylene terephthalate (PET) and polyurethane (PU), and their combination. A strength of the support layer 152 formed of the polymer materials can be controlled by adding additives to increase a thickness and strength of the support layer 152. Further, the support layer 152 can be formed of glass, ceramic, metal, other rigid materials, or combinations of the above materials. The support layer 152 can have a film shape or a foam shape.

The adhesive layer 151 can include a second buffer pattern 132. Structurally, the second buffer pattern 132 can be arranged between the adhesive layer 151 and the support layer 152. In more detail, the second buffer pattern 132 can have a shape that is concave toward the center of the adhesive layer 151 between the adhesive layer 151 and the support layer 152.

When the bending area BA of the substrate 110 is bent at a predetermined radius of curvature, the second buffer pattern 132 can disperse bending stress generated by bending of the substrate 110 together with the first buffer pattern 131 and suppress or minimize occurrence of cracks in and around the bending area BA due to an external force.

The second buffer pattern 132 is shown to have a semicircular shape, but an embodiment of the present disclosure is not limited thereto. The second buffer pattern 132 can be designed to have various shapes, as necessary, such as a trapezoidal shape, a stepwise shape, a square shape, and a pentagonal shape, in addition to the semicircular shape.

At least a portion of the second buffer pattern 132 can overlap the first buffer pattern 131.

As at least a portion of the second buffer pattern 132 overlaps the first buffer pattern 131, the second buffer pattern 132 can disperse bending stress generated by bending of the substrate 110 together with the first buffer pattern 131 when the bending area BA of the substrate 110 is bent at a predetermined radius of curvature, and suppress or minimize cracks that can occur in and around the bending area BA due to an external force.

According to another embodiment of the present disclosure, the second buffer pattern 132 can include a third resin layer 143.

The third resin layer 143 can include a second polymer matrix.

The third polymer matrix is a material formed from a binder compound, and is a base material constituting the third resin layer 143. The third polymer matrix can be a polymer resin having heat resistance and a higher elastic modulus than the substrate 110.

The third polymer matrix can be formed by polymerization of the binder compound. The binder compound forming the third polymer matrix can be a thermosetting or thermoplastic polymer resin.

The third polymer matrix can be formed by polymerization of the same binder compound as the first polymer matrix or the second polymer matrix. A detailed type of the binder compound is the same as that described above in the first polymer matrix, and thus will be omitted.

FIG. 10 is a schematic cross-sectional view illustrating a display panel 800 according to another embodiment of the present disclosure.

Referring to FIG. 10, the display panel 800 according to another embodiment of the present disclosure has the same structure as the display panel 700 according to another embodiment of the present disclosure, but is different in that the first resin layer 141 further includes a first thermally conductive filler dispersed in the first polymer matrix, the second resin layer 142 further includes a second thermally conductive filler dispersed in the second polymer matrix, and the third resin layer 143 further includes a third thermally conductive filler dispersed in the third polymer matrix. Hereinafter, only portions different from the display panel 700 according to an embodiment of the present disclosure will be described.

The third resin layer 143 can include a third polymer matrix and a third thermally conductive filler dispersed in the third polymer matrix.

The third thermally conductive filler gives insulation to the third resin layer 143 and simultaneously improves heat dissipation performance. The third thermally conductive filler is dispersed in the third polymer matrix. The third thermally conductive filler can have a particle shape or a fiber shape. When the third thermally conductive filler has a particle shape, dispersibility can be improved through surface treatment, coupling agent, or the like of the filler. When the third thermally conductive filler has a fiber shape, orientation can be controlled to have anisotropy in the third polymer matrix through a solvent, a surface treatment agent, or the like. When at least one of the particle shaped filler with improved dispersibility or the fiber shaped filler with controlled orientation is used as the third thermally conductive filler, the third resin layer 143 can have excellent thermal conductivity.

The third thermally conductive filler can be the same as the first thermally conductive filler. A detailed type of the third thermally conductive filler is the same as that described above in the first thermally conductive filler, and thus will be omitted.

In the display panel 800 according to another embodiment of the present disclosure, as the first resin layer 141 includes the first thermally conductive filler, the second resin layer 142 includes the second thermally conductive filler, and the third resin layer includes the third thermally conductive filler, heat generated from the display unit 10 and the line 30 can be effectively reduced.

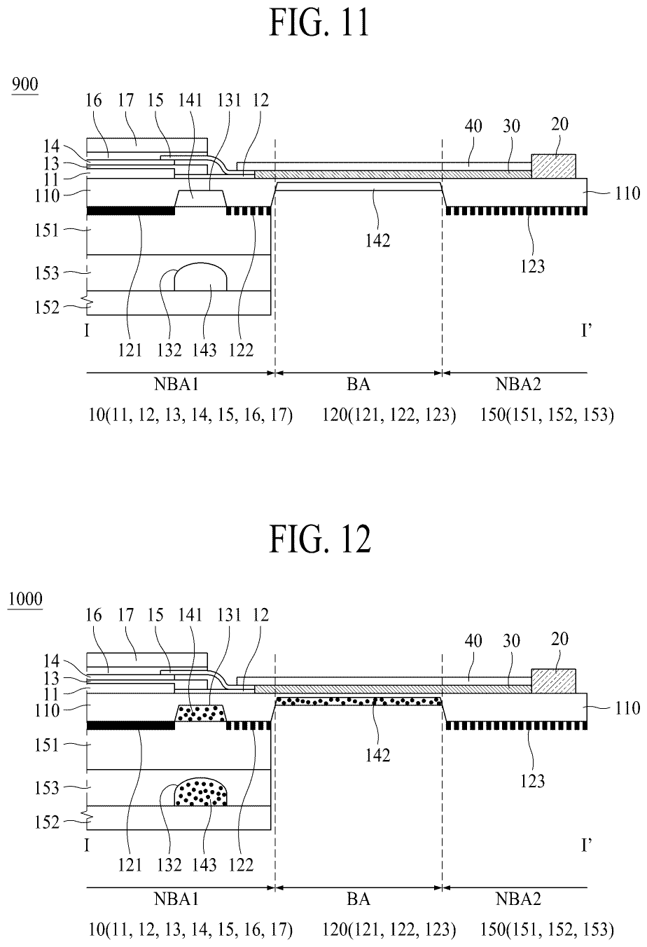

FIG. 11 is a schematic cross-sectional view illustrating a display panel 900 according to another embodiment of the present disclosure.

Referring to FIG. 11, the display panel 900 according to another embodiment of the present disclosure has the same structure as that of the display panel 700 according to another embodiment of the present disclosure, but is different in that the display panel 900 further includes a hard coating layer 153 between the adhesive layer 151 and the support layer 152, and the second buffer pattern is arranged between the hard coating layer 153 and the support layer 152. Hereinafter, only portions different from the display panel 700 according to an embodiment of the present disclosure will be described.

The display panel 900 according to another embodiment of the present disclosure can further include a hard coating layer 153 between the adhesive layer 151 and the support layer 152 to protect the first black pattern layer 122.

The hard coating layer 153 can include a second buffer pattern 132. The second buffer pattern 132 can be arranged between the hard coating layer 153 and the support layer 152. In more detail, the second buffer pattern 132 can be arranged to be concave toward the center of the hard coating layer 153 between the hard coating layer 153 and the support layer 152. The third resin layer 143 can be arranged in the second buffer pattern 132.

At least a portion of the second buffer pattern 132 can overlap the first buffer pattern 131.

As at least a portion of the second buffer pattern 132 overlaps the first buffer pattern 131, the second buffer pattern 132 can disperse bending stress generated by bending of the substrate 110 together with the first buffer pattern 131 when the bending area BA of the substrate 110 is bent at a predetermined radius of curvature, and can suppress or minimize cracks that can occur in and around the bending area BA due to an external force.

FIG. 12 is a schematic cross-sectional view illustrating a display panel 1000 according to another embodiment of the present disclosure.

Referring to FIG. 12, the display panel 1000 according to another embodiment of the present disclosure has the same structure as that of the display panel 900 according to another embodiment of the present disclosure, but is different in that the first resin layer 141 further includes a first thermally conductive filler dispersed in the first polymer matrix, the second resin layer 142 further includes a second thermally conductive filler dispersed in the second polymer matrix, and the third resin layer 143 further includes a third thermally conductive filler dispersed in the third polymer matrix.

In the display panel 1000 according to another embodiment of the present disclosure, as the first resin layer 141 includes the first thermally conductive filler, the second resin layer 142 includes the second thermally conductive filler, and the third resin layer includes the third thermally conductive filler, heat generated from the display unit 10 and the line 30 can be effectively reduced.

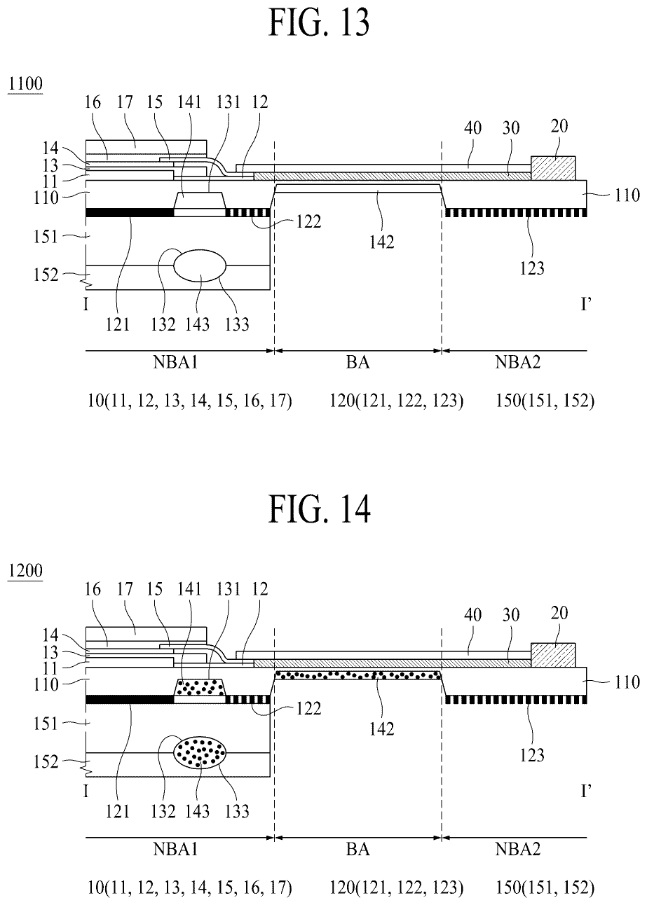

FIG. 13 is a schematic cross-sectional view illustrating a display panel 1100 according to another embodiment of the present disclosure.

Referring to FIG. 13, the display panel 1100 according to another embodiment of the present disclosure has the same structure as that of the display panel 900 according to another embodiment of the present disclosure, but there is a difference in that the support layer 152 further includes a third buffer pattern 133. Hereinafter, only portions different from the display panel 900 according to an embodiment of the present disclosure will be described.

The display panel 1100 according to another embodiment of the present disclosure can include an adhesive layer 151 and a support layer 152, the adhesive layer 151 can include a second buffer pattern 132, and the support layer 152 can include a third buffer pattern 1521.

The second buffer pattern 132 and the third buffer pattern 133 can face each other. A structure in which an opening of the second buffer pattern 132 and an opening of the third buffer pattern 133 face each other can be defined as a structure in which the second buffer pattern 132 and the third buffer pattern 133 face each other.

The third resin layer 143 can be arranged in the second buffer pattern 132 and the third buffer pattern 133. In more detail, the inside of the second buffer pattern 132 and the inside of the third buffer pattern 133 can be filled by the third resin layer 143.

At least a portion of the second buffer pattern 132 can overlap the first buffer pattern 131.

As at least a portion of the second buffer pattern 132 overlaps the first buffer pattern 131, the second buffer pattern 132 can disperse bending stress generated by bending of the substrate 110 together with the first buffer pattern 131 when the bending area BA of the substrate 110 is bent at a predetermined radius of curvature, and can suppress or minimize cracks that can occur in and around the bending area BA due to an external force.

FIG. 14 is a schematic cross-sectional view illustrating a display panel 1200 according to another embodiment of the present disclosure.

Referring to FIG. 14, the display panel 1200 according to another embodiment of the present disclosure has the same structure as that of the display panel 1100 according to another embodiment of the present disclosure, but is different in that the first resin layer 141 further includes a first thermally conductive filler dispersed in the first polymer matrix, the second resin layer 142 further includes a second thermally conductive filler dispersed in the second polymer matrix, and the third resin layer 143 further includes a third thermally conductive filler dispersed in the third polymer matrix.

In the display panel 1200 according to another embodiment of the present disclosure, as the first resin layer 141 includes the first thermally conductive filler, the second resin layer 142 includes the second thermally conductive filler, and the third resin layer includes the third thermally conductive filler, heat generated from the display unit 10 and the line 30 can be effectively reduced.

According to another embodiment of the present disclosure, the display panel 1200 can further include a back plate member on the support layer 152 as necessary.

The back plate member can be coupled to or attached to the support layer 152. In more detail, the back plate member can be coupled or attached onto the support layer 152 by a back plate bonding member. The back plate bonding member can include any one of, for example, a Pressure Sensitive Adhesive (PSA), an Optical Clear Adhesive (OCA), and an Optical Clear Resin (OCR).

The back plate member can include a metal material. In detail, the back plate member can include a metal layer. In more detail, the back plate member can include a metal plate made of a metal material having excellent thermal conductivity. The back plate member can be, for example, a heat dissipation member, a heat dissipation plate, a shield member, a signal shielding member, a heat dissipation tape, a heat dissipation cushion tape, a conductive heat dissipation tape, a heat dissipation sheet, a heat dissipation ground sheet, or a conductive heat dissipation sheet.

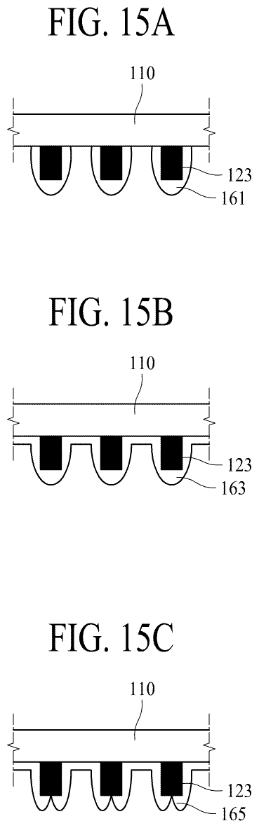

FIGS. 15A, 15B and 15C are schematic cross-sectional views illustrating various shapes of protective layers 161, 163 and 165.

The display panels 100, 200, 300, 400, 500, 600, 700, 800, 900, 1000, 1100 and 1200 according to an embodiment of the present disclosure can further include at least one protective layer among the protective layers shown in FIGS. 15A, 15B and 15C.

According to another embodiment of the present disclosure, the protective layers 161, 163 and 165 can be formed on at least one of the first black pattern layer 122 or the second black pattern layer 123.

As the protective layers 161, 163 and 165 are formed on at least one of the first black pattern layer 122 or the second black pattern layer 123, an area with which the substrate 110 is in direct contact can be minimized before a bending process, whereby occurrence of cracks in and around the bending area BA in accordance with handling during an assembly process of the display panel can be suppressed or minimized.

In addition, when a bending state is fixed through the fixed layer 150 after bending of the substrate 110, a contact area between the substrate 110 and the fixed layer 150 can be increased, whereby adhesion between the substrate 110 and the fixed layer 150 can be improved.

Referring to FIG. 15A, the protective layer 161 can be formed on at least one of the first black pattern layer 122 or the second black pattern layer 123, and can be formed to cover at least one of the first black pattern layer 122 or the second black pattern layer 123. In this case, the protective layer 161 is spaced apart from another adjacent protective layer 161. Accordingly, a portion of the substrate 110, which is not covered by the protective layer 161,s can be exposed. Although FIG. 15A illustrates that the protective layer 161 is formed on the second black pattern layer 123, the protective layer 161 can also be formed on the first black pattern layer 122 included in the display panels 100, 200, 300, 400, 600, 700, 800, 900, 1000, 1100 and 1200.

Referring to FIG. 15B, the protective layer 163 can be formed on at least one of the first black pattern layer 122 or the second black pattern layer 123, and can be formed to cover at least one of the first black pattern layer 122 or the second black pattern layer 123. The protective layer 163 can also be formed on a space between patterns included in the first black pattern layer 122 or the second black pattern layer 123. Accordingly, the protective layer 163 can be connected to another adjacent protective layer 163, and can cover the substrate 110. Although FIG. 15B illustrates that the protective layer 163 is formed on the second black pattern layer 123, the protective layer 163 can also be formed on the first black pattern layer 122 included in the display panels 100, 200, 300, 400, 500, 600, 700, 800, 900, 1000, 1100 and 1200.

Referring to FIG. 15C, the protective layer 165 can be formed on at least one of the first black pattern layer 122 or the second black pattern layer 123, and can be formed to cover at least one of the first black pattern layer 122 or the second black pattern layer 123. The protective layer 165 can also be formed on a space between patterns included in the first black pattern layer 122 or the second black pattern layer 123. Further, the protective layer 165 can be formed to have a predetermined pattern on a surface thereof. In more detail, the protective layer 165 can be formed to have a protruded pattern on a surface thereof. Although FIG. 15C illustrates that the protective layer 165 is formed on the second black pattern layer 123, the protective layer 165 can also be formed on the first black pattern layer 122 included in the display panels 100, 200, 300, 400, 500, 600, 700, 800, 900, 1000, 1100 and 1200.

The protective layers 161, 163 and 165 can include an epoxy resin and a filler.

The epoxy resin has excellent heat resistance and has excellent adhesion to the adhesive layer 151 included in the fixed layer 150.

The epoxy-based resin can include, for example, at least one of a novolac-type epoxy resin, a biphenyl-type epoxy resin, a bisphenol A-type epoxy resin, a bisphenol F-type epoxy resin, a bisphenol S-type epoxy resin, a glycidyl amine-based epoxy resin, or a glycidyl ester-based epoxy resin.

In more detail, the epoxy resin can include any one of, for example, a diphenylolpropane epoxy resin, a diphenylolmethane epoxy resin, and a diamine epoxy resin.

The diphenylolpropane epoxy resin can include, for example, a compound having a structure represented by Chemical Formula 1 below.

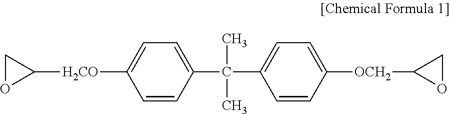

The diphenylolmethane epoxy resin can include, for example, a compound having a structure represented by Chemical Formula 2 below.

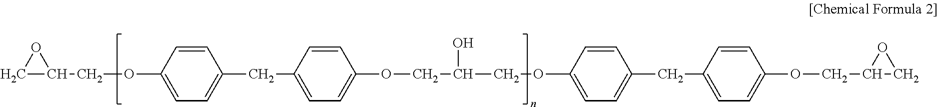

The diamine epoxy resin can include, for example, a compound having a structure represented by Chemical Formula 3 below.

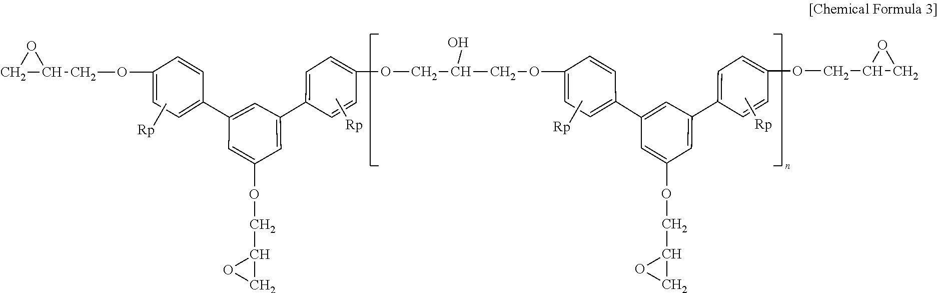

In the Chemical Formula 3, R is alkyl or phenyl of C1 to C12, which are independent from one another, p is an integer of 0 to 2, and n is an integer of 0 to 10.

However, embodiments of this invention are not limited to the above examples, and other known materials in addition to the epoxy resin can be used to form the protective layer 161.

The filler can include at least one of, for example, a spherical filler or a fibrous filler.

As the spherical filler, for example, at least one of aluminum nitride (AlN), silver (Ag), beryllium oxide (BeO), silicon carbide (SiC) or magnesium oxide (MgO) can be used. As the fibrous filler, for example, at least one of graphite, graphene, carbon nanotube (CNT) or carbon nanofiber (CNF) can be used.

A surface-treated filler can be used to improve dispersibility of the filler in the resin. Alternatively, an additive such as a coupling agent can be used to improve dispersibility of the filler in the resin.

According to another embodiment of the present disclosure, when the protective layers 161, 163 and 165 including the epoxy-based resin and the filler are formed on at least one of the first black pattern layer 122 or the second black pattern layer 123, heat dissipation characteristics can be improved.

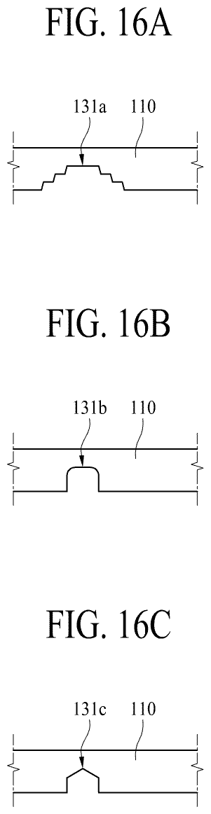

FIGS. 16A, 16B and 16C are schematic cross-sectional views illustrating various shapes of a first buffer pattern. Particularly, FIGS. 16A, 16B and 16C are schematic cross-sectional views illustrating various shapes of the first buffer pattern 131 included in the display panels 100, 200, 300, 400, 500, 600, 700, 800, 900, 1000, 1100 and 1200 according to an embodiment of the present disclosure.

Referring to FIG. 16A, the first buffer pattern 131a can have a stepwise shape.

Referring to FIG. 16B, the first buffer pattern 131b can have a rectangular shape with rounded corners.

Referring to FIG. 16C, the first buffer pattern 131c can have a pentagonal shape.

According to another embodiment of the present disclosure, when the first buffer pattern 131 has any one shape of FIGS. 16A, 16B and 16C, when the bending area BA of the substrate 110 is bent at a predetermined radius of curvature, bending stress caused by bending of the substrate 110 can be dispersed, and occurrence of cracks in and around the bending area BA due to an external force can be suppressed or minimized.

However, embodiments of the present disclosure are not limited to the above examples.

Since the display apparatus according to another embodiment of the present disclosure includes the above-described display panels, occurrence of cracks in and around the bending area BA due to an external force can be suppressed or minimized, and can have excellent heat dissipation characteristics.

The display panels according to the embodiment of the present disclosure have been described as flexible light emitting display panels, but are not limited thereto, and can be changed to a known flexible display panel including a flexible liquid crystal display panel or a flexible electrophoretic display panel.

The display apparatus according to another embodiment of the present disclosure is not limited to a smart phone, a mobile communication terminal, or a mobile phone, but can be a tablet PC, a smart watch, a watch phone, a wearable device, an electronic diary, an electronic book, a portable multimedia player (PMP), a navigator, a television, a laptop, a monitor, a camera, a camcorder, or a home appliance.

According to the present disclosure, the following advantageous effects can be obtained.

According to an embodiment of the present disclosure, cracks that can occur in the display panel during the assembly process of the display apparatus and the user's product use process can be suppressed.

According to an embodiment of the present disclosure, heat generated in the process of using the display apparatus by the user can be effectively suppressed.

It will be apparent to those skilled in the art that the present disclosure described above is not limited by the above-described embodiments and the accompanying drawings and that various substitutions, modifications and variations can be made in the present disclosure without departing from the spirit or scope of the disclosures. Consequently, the scope of the present disclosure is defined by the accompanying claims and it is intended that all variations or modifications derived from the meaning, scope and equivalent concept of the claims fall within the scope of the present disclosure.

What is claimed is:

1. A display panel comprising:
a substrate; and
a light shielding layer on the substrate,
wherein the substrate includes a bending area, a first non-bending area, and a second non-bending area,
wherein the bending area is arranged between the first non-bending area and the second non-bending area,
wherein the light shielding layer includes:
a black coating layer arranged in the first non-bending area;
a first black pattern layer arranged in the first non-bending area; and
a second black pattern layer arranged in the second non-bending area,
wherein the first non-bending area includes a first buffer pattern, and
wherein the first buffer pattern is arranged between the black coating layer and the first black pattern layer.

2. The display panel of claim 1, wherein the first buffer pattern has a thickness being smaller than thicknesses of the first and second non-bending areas and being greater than a thickness of the bending area.

3. The display panel of claim 2, further comprising a first resin layer arranged in the first buffer pattern.

4. The display panel of claim 3, wherein the first resin layer includes:
a first polymer matrix; and
a first thermally conductive filler dispersed in the first polymer matrix.

5. The display panel of claim 1, further comprising a second resin layer arranged in an area defined by the bending area, the first non-bending area, and the second non-bending area.

6. The display panel of claim 5, wherein the second resin layer includes:
a second polymer matrix; and
a second thermally conductive filler dispersed in the second polymer matrix.

7. The display panel of claim 1, further comprising a third black pattern layer arranged between the first buffer pattern and the black coating layer.

8. The display panel of claim 4, further comprising a fourth black pattern layer on the first resin layer.

9. The display panel of claim 8, wherein the fourth black pattern layer includes a same material as the first polymer matrix.

10. The display panel of claim 8, wherein the fourth black pattern layer includes a same material as the first black pattern layer.

11. The display panel of claim 1, further comprising a protective layer arranged on at least one of the first black pattern layer or the second black pattern layer.

12. The display panel of claim 1, further comprising:
an adhesive layer on the light shielding layer;
a support layer on the adhesive layer; and
a second buffer pattern arranged between the adhesive layer and the support layer.

13. The display panel of claim 12, wherein at least a portion of the second buffer pattern overlaps the first buffer pattern.

14. The display panel of claim 12, further comprising a third resin layer arranged in the second buffer pattern,
wherein the third resin layer includes:
a third polymer matrix; and
a third thermally conductive filler dispersed in the third polymer matrix.

15. The display panel of claim 12, further comprising a hard coating layer between the adhesive layer and the support layer.

16. The display panel of claim 12, wherein the adhesive layer includes a second buffer pattern,
the support layer includes a third buffer pattern, and
the second buffer pattern and the third buffer pattern face each other.

17. The display panel of claim 16, further comprising a third resin layer arranged in the second buffer pattern and the third buffer pattern,
wherein the third resin layer includes:
a third polymer matrix; and
a third thermally conductive filler dispersed in the third polymer matrix.

18. A display device comprising the display panel of claim 1.
